(19) United States
(12) Patent Application Publication
(10) Pub. No.: US 2026/0343830 A1
(43) Pub. Date: Oct. 29, 2026

(54) COOLANT DISTRIBUTION UNIT LOAD BALANCING CONTROL ALGORITHM FOR ADAPTIVE THERMAL MANAGEMENT

(71) Applicant: Dell Products L.P., Round Rock, TX (US)

(72) Inventors: Prabhakar Subrahmanyam, San Jose, CA (US); Timothy Allen Shedd, Lithia, FL (US); Rizwan Ali, Cedar Park, TX (US)

(21) Appl. No.: 19/191,587

(22) Filed: Apr. 28, 2025

(51) Int. Cl. H05K 7/20; G06F 1/20

(52) U.S. Cl. CPC H05K 7/20836; G06F 1/206; H05K 7/20781

(57) ABSTRACT

A method for load balancing a computing system including checking a first load balancing criteria for a first server of the computing system using a controller of a coolant distribution unit (CDU). The controller chooses an appropriate algorithm based on a predetermined mapping in the CDU. Further, the method includes making a first determination that the first load balancing criteria needs to be rebalanced. The controller uses an information technology load, a workload change, and a higher power dissipation in the first server to make the first determination. Moreover, the method includes making a second determination, based on the first determination, to identify a location of the first server. Finally, the method includes adjusting a CDU cooling strategy, based on the second determination, by modifying a first coolant flow to the first server to rebalance the first load balancing criteria.

### BACKGROUND

High-density liquid cooling is becoming increasingly critical for managing the thermal loads generated by modern data centers, particularly those supporting high-performance computing, artificial intelligence (AI) applications and cloud computing. In many of these data centers each server (or chassis) may be equipped with at least eight graphics processing units (GPUs) and two central processing units (CPUs) which each having an associated cold plate leading to over one hundred cold plates per rack all connected to a coolant distribution unit (CDU).

### BRIEF DESCRIPTION OF DRAWINGS

Certain embodiments disclosed herein will be described with reference to the accompanying drawings. However, the accompanying drawings illustrate only certain aspects or implementations of one or more embodiments disclosed herein by way of example and are not meant to limit the scope of the claims.

FIG. 1.1 shows a diagram of a system in accordance with one or more embodiments disclosed herein.

FIG. 1.2 shows a sever rack in accordance with one or more embodiments disclosed herein.

FIG. 1.3 shows a front view of the server rack in accordance with one or more embodiments disclosed herein.

FIG. 1.4 shows a diagram of a cooling system in accordance with one or more embodiments disclosed herein.

FIG. 2.1 shows a diagram of a coolant distribution unit in accordance with one or more embodiments disclosed herein.

FIG. 2.2 shows a diagram of a manifold for the server rack in accordance with one or more embodiments disclosed herein.

FIG. 2.3 shows a side view of a portion of the server rack in accordance with one or more embodiments disclosed herein.

FIG. 3 shows a flowchart for a method for responding to leaks in a computing system in accordance one or more embodiments disclosed herein.

FIG. 4 shows a flowchart for a method for detecting anomalies in a coolant system of a computing system in accordance one or more embodiments disclosed herein.

FIG. 5 shows a flowchart for a method for responding to leaks in a computing system in accordance one or more embodiments disclosed herein.

FIG. 6 shows a flowchart for a method for responding to leaks in a computing system in accordance one or more embodiments disclosed herein.

FIG. 7 shows a flowchart for a method for load balancing a computing system in accordance one or more embodiments disclosed herein.

FIG. 8 shows a diagram of a computing device in accordance with one or more embodiments disclosed herein.

### DETAILED DESCRIPTION

In traditional data centers, the risk of coolant leaks presents a significant challenge to system reliability and uptime. Often when a leak occurs an entire rack is shut down creating significant downtime. Due to the bandwidth of artificial intelligence and cloud computing applications dictating higher workload and computational efficiency for search, learning and inference, data centers may have over one hundred cold plates per rack. This increase in the cold plate count increases the potential for leaks significantly. In a large-scale implementation of over 1000 racks in a data center, finding a single or multiple cold plates leaking can be a challenging proposition especially when they occur in distributed racks in data center environment. Commercially available coolant distribution units (CDUs) do not have the ability to isolate leaks. The CDUs shut down the entire rack and are often not automated, requiring manual intervention. In large scale rack implementation, it is resource intensive to identify, isolate and drive a resolution for leak detection swiftly. Traditional data centers also do not use historical data, perform anomaly detection for preventive maintenance, or perform load balancing with the CDU. For at least the reasons discussed above, a different approach for load balancing, preventing and correcting leaks may be beneficial.

Embodiments disclosed herein relate to load balancing across servers, identifying and addressing leaks in a coolant system, and detecting anomalies to prevent leaks in a data center using a CDU with a specialized controller allowing for differentiation of coolant flow. Load balancing includes the controller having an AI-enhanced coolant control for optimized data center cooling. Adaptive load balancing algorithm maintains components at optimal temperatures by using preemptive cooling. The load balancing algorithm allows for real time and predictive load balancing.

Addressing leaks includes identifying an isolated leak when it happens, and, through a combination of the CDU controller and a built-in machine learning algorithm, accurately pinpointing the grid location of the rack in a multiple rack implementation in the data center. The multiple rack implementation may include smaller implementations (e.g., about 500 racks or less) or larger implementations (e.g., 5000 racks or more). Further, the embodiments herein may be scaled to the number of racks in the implementation. Once the grid location of the rack is identified, the CDU controller identifies the server within a specific rack and may also locate the leaking component (e.g., a leaky cold plate). The CDU controller may shut off the coolant flow to that specific cold plate and ensures that the power is shut off to the defective (leaky) cold plate's package (graphics processing unit (GPU) or central processing unit (CPU)) to prevent thermal runaway. This idea enables rapid identification of the affected racks, servers, and individual cold plates, triggering automated responses such as coolant flow shut-off and component power down. Furthermore, it seamlessly integrates with data center management systems to provide real-time alerts and detailed information for efficient maintenance and repair. Anomalies may also be detected using a machine learning algorithm that collects and analyzes historical data to predict future temperature needs dictated by workload changes and detect anomalies preventing a potential leak or downtime scenario.

The following describes various embodiments disclosed herein.

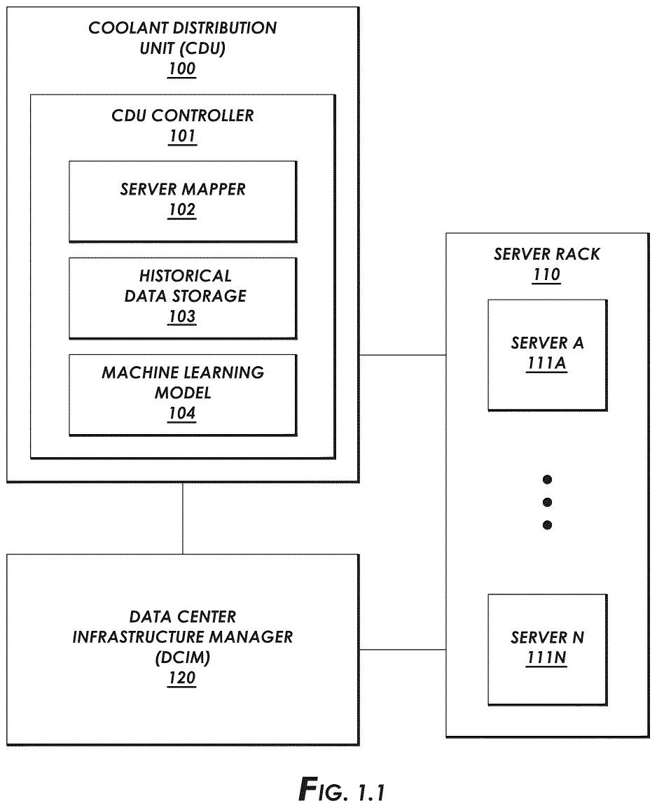

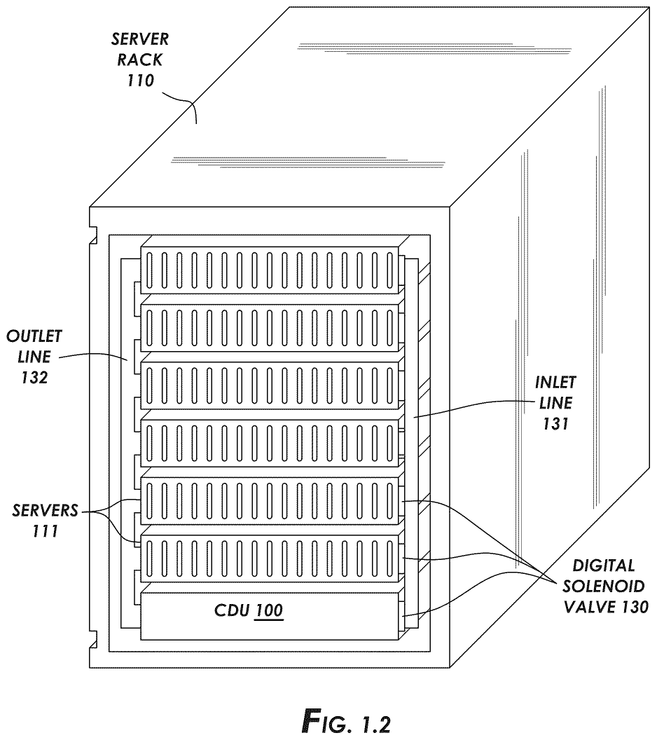

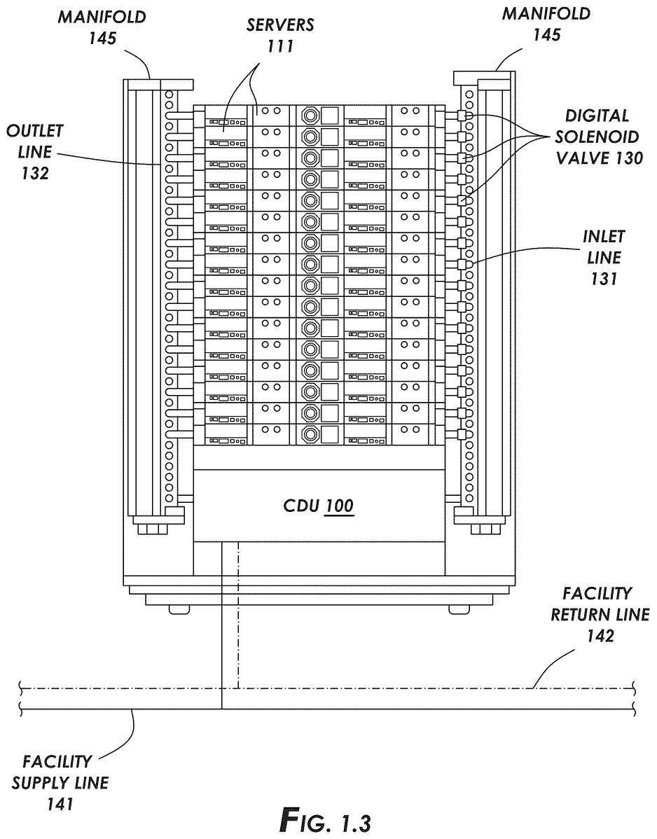

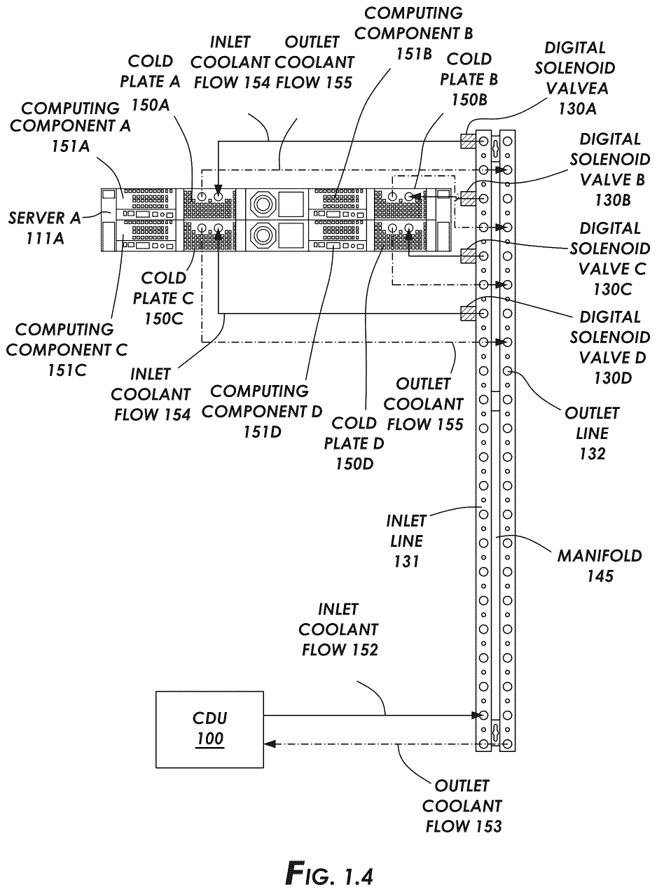

FIG. 1.1 shows a diagram of a system in accordance with one or more embodiments disclosed herein. The system includes a coolant distribution unit (CDU) (100), a server rack (110), and a data center infrastructure manager (DCIM) (120). Each of these components shown in FIG. 1 is described below.

The system may include additional, fewer, and/or different components without departing from the scope of the embodiments disclosed herein. Each component may be operably/operatively connected to any of the other components via any combination of wired and/or wireless connections (including connections to local area networks, wireless networks, and wide area networks). For example, the components shown in FIG. 1 may be connected via a network fabric (not shown). A network fabric refers to the interconnected topology and structure of network elements (e.g., switches, routers, and links, which work together to provide data transmission within between the components). The network fabric may be implemented using a spine-leaf topology, where every leaf switch connects to each spine switch. Those skilled in the art will appreciate that any other type of network (or network topology) may be used without departing from the disclosure.

In one or more embodiments, the CDU (100) includes functionality to provide cooling as shown in FIGS. 1.2-1.4, and 2.1. The CDU (100) provides flow control for coolant of a coolant system. The CDU (100) includes a CDU controller (101) to control the CDU (100). The CDU (100) is connected to the server rack (110) and includes functionality to provide coolant to the server rack (110). The CDU (100) is further described in FIGS. 1.2 and 2.1.

The CDU controller (101) includes functionality to operate the CDU (100). The CDU controller (101) controls flow characteristics, temperature, and/or pressure of fluid flowing through the CDU (100) and flowing through the coolant system to the plurality of servers (111A, 111N) of the server rack (110). The CDU controller (101) includes a server mapper (102), a historical data storage (103), and a machine learning (ML) model (104). The server mapper (102) includes a map of all servers in the data center including a server identification, a rack the server is located, and a row in the rack the server is located. Other information of the server included is a location of cold plates and components in the server, identifications of the cold plates and components in the server.

The historical data storage (103) is a storage that records all the historical data from the CDU including temperatures of coolant flowing from the CDU, into the CDU, entering the plurality of cold plates and exiting the plurality of cold plates. The historical data further includes the flow rate of the coolant flowing from the CDU, into the CDU, entering the plurality of cold plates and exiting the plurality of cold plates. Prior leak occurrences including location and time of the leak are stored in the historical data. In one or more embodiments, historical usage data for the servers is stored in the historical data. The ML model (104) may be a random forest model. The ML model includes functionality to collect and analyze historical data to predict future temperature needs based on workflow of the servers and detect anomalies to prevent potential leaks and downtime. Preventive maintenance may be completed based on the detected anomalies.

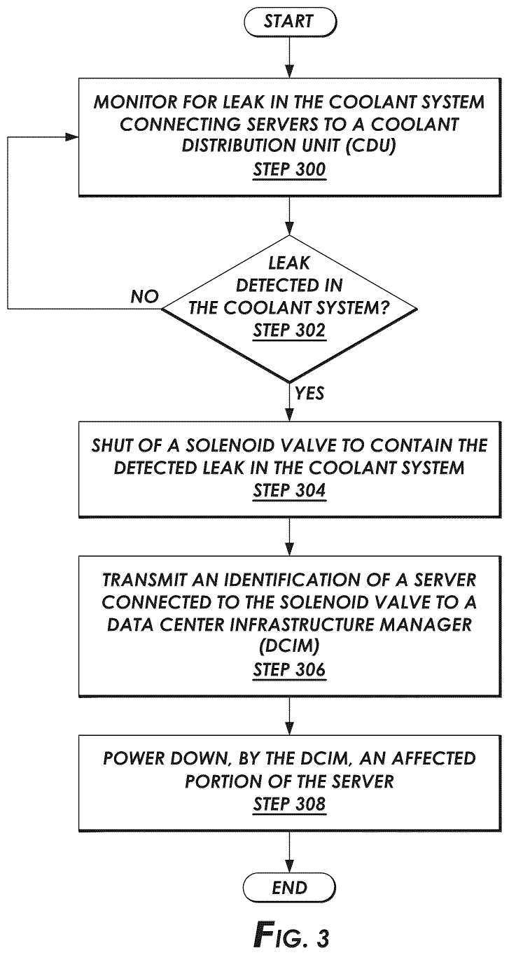

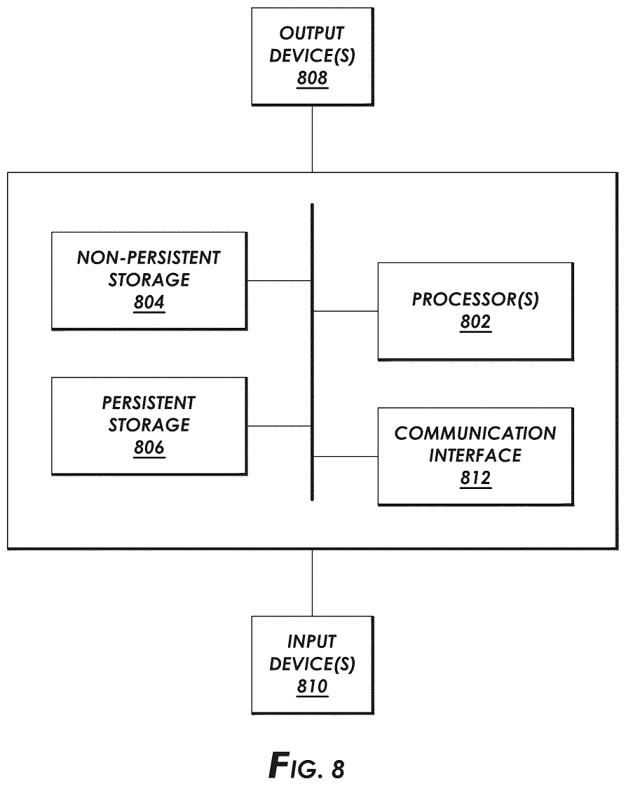

In one or more embodiments, the CDU controller (101) may be implemented as one or more computing devices (see e.g., FIG. 8). The computing device(s) may be, for example, a server, a distributed computing system, or a cloud resource. The computing device may include one or more processors, memory (e.g., random access memory), and persistent storage (e.g., disk drives, solid state drives, etc.). The computing device may provide the functionality of the CDU controller (101) described throughout this application and/or all, or a portion thereof, of the method illustrated in FIGS. 3-7.

In one or more embodiments, the CDU controller (101) may be implemented as a logical device(s) (e.g., a virtual machine). Each logical device may utilize the computing resources of any number of computing devices and thereby provide the functionality of the CDU controller (101) described throughout this application and/or all, or a portion thereof, of the method illustrated in FIGS. 3-7.

The server rack (110) includes a plurality of servers (111A, 111N). The plurality of servers (111A, 111N) may include a server A (111A), a server N (111N), and any other server. The server rack (110) is operatively connected to the CDU (100) so the CDU (100) may provide cooling to the plurality of servers (111A, 111N) in the server rack (110). While only one server rack is shown, the disclosure contemplates multiple server racks (110) being connected to the CDU (100).

In one or more embodiments, the plurality of servers (111A, 111N) may be implemented as one or more computing devices (see e.g., FIG. 8). The computing device(s) may be, for example, a server, a distributed computing system, or a cloud resource. The computing device may include one or more processors, memory (e.g., random access memory), and persistent storage (e.g., disk drives, solid state drives, etc.). The computing device may provide the functionality of the plurality of servers (111A, 111N) described throughout this application and/or all, or a portion thereof, of the method illustrated in FIGS. 3-7.

The DCIM (120) provides functionality to control the status of the plurality of servers. For example, the DCIM (120) may power down a server of the plurality of servers. In one or more embodiments, the DCIM (120) is operatively connected to the CDU (100) to receive data (e.g., temperature, pressure, coolant mass flow rate). The CDU (100) will also communicate servers or components of servers that need to be shut down to the DCIM (120).

In one or more embodiments, the DCIM (120) may be implemented as one or more computing devices (see e.g., FIG. 8). The computing device(s) may be, for example, a server, a distributed computing system, or a cloud resource. The computing device may include one or more processors, memory (e.g., random access memory), and persistent storage (e.g., disk drives, solid state drives, etc.). The computing device may provide the functionality of the DCIM (120) described throughout this application and/or all, or a portion thereof, of the method illustrated in FIGS. 3-7.

In one or more embodiments, the DCIM (120) may be implemented as a logical device(s). Each logical device may utilize the computing resources of any number of computing devices and thereby provide the functionality of the DCIM (120) described throughout this application and/or all, or a portion thereof, of the method illustrated in FIGS. 3-7.

Turning to FIG. 1.2, FIG. 1.2 shows the server rack (110) in accordance with one or more embodiments disclosed herein. FIG. 1.2 is the physical representation of the server rack and includes the system of FIG. 1.1. The server rack (110) includes the plurality of servers (111), the CDU (100), a plurality of digital solenoid valves (130), an inlet line (131), an outlet line (132) and the DCIM (not shown).

The server rack (110) may be a mechanical structure that enables servers to be positioned with respect to one another. For example, the server rack (110) may be a rack mount enclosure that enables servers to be disposed within it. The server rack (110) may be implemented as other types of structures adapted to house, position, orient, and/or otherwise physically, mechanically, electrically, and/or thermally manage servers (e.g., direct airflows to the servers). By managing the servers, the server rack (110) may enable multiple servers to be densely packed in space without negatively impacting the operation of a data center. In FIG. 1.2, the servers are shown stacked one on top of another in the server rack (110)

In one or more embodiments, a chassis (not shown) may be a mechanical structure for housing multiple servers side by side in a level of the server rack (110). For example, a chassis may be implemented as a rack mountable enclosure for housing servers. The chassis may be adapted to be disposed within the server rack (110) and/or utilize services provided by the server rack (110) and/or other devices.

Any number of servers may be disposed in the server rack (110). These servers may include multiple computing components (e.g., GPUs, CPUs. data processing units, etc.) that provide computer implemented services, as discussed above.

When the components of the servers provide computer implemented services, the components may generate heat. For example, the components may utilize electrical energy to perform computations and generate heat as a byproduct of performing the computations. If left unchecked, a buildup of heat within a server may cause temperatures of the components disposed within the chassis to exceed preferred ranges.

The preferred ranges may include a nominal range in which the components respectively operate: (i) without detriment and/or (ii) are likely to be able to continue to operate through a predetermined service life of a component. Consequently, it may be desirable to maintain the temperatures of the respective components within the preferred range (e.g., a nominal range).

When a component operates outside of the preferred range, the service life of the component may be reduced, the component may not be able to perform optimally (e.g., reduced ability to provide computations, higher likelihood of error introduced into computations, etc.), and/or the component may be more likely to unexpectedly fail. The component may be subject to other undesirable behavior when operating outside of the preferred range without departing from the embodiments disclosed here.

To operate components within the preferred range of temperature, the CDU (100) exchanges coolant with the components and servers via the coolant system. The coolant system includes a manifold that connects the CDU (100) to one or more openings in an exterior of a server via the inlet line (131) and the outlet line (132) that enables the servers to exchange coolant (e.g., fluid) with CDU (100). For example, a server may utilize an inlet to receive a coolant flow from the inlet line (131), then pass through the coolant flow through one or more cold plates (e.g., internal heat exchangers) to remove heat from one or more components contained within the server. The server may then utilize an outlet to expel the now heated coolant flow to the CDU (100) configured to receive the coolant flow from the servers via the outlet line (132). Consequently, the temperatures of components within the server may be reduced by utilizing the cooler coolant taken into the server via a fluid exchange. The coolant flow from the CDU (100) to the servers back to the CDU (100) is described further in FIG. 1.4.

The plurality of digital solenoid valves (130) are positioned on the inlet line (131) or between the inlet line and a specific server to block coolant from reaching the specific server. In one or more embodiments, as shown in FIG. 1.4, multiple digital solenoid valves (130) may be positioned between the inlet line (131) and the server to block coolant flow to specific cold plates in the server to allow coolant to flow to other cold plates of the server. The digital solenoid valves (130) include functionality to stop the flow of coolant through it. The digital solenoid valves (130) are operatively connected to the CDU controller (101) which controls whether each digital solenoid valves (130) are open or closed to coolant flow. In one or more embodiments, the digital solenoid valves (130) include functionality to partially open and close to control the mass flow rate of coolant that passes through them. In one or more embodiments, each server has a main digital solenoid valve and each cold plate in each server has a secondary digital solenoid valve allowing for coolant to be shut off to a single cold plate or an entire server.

FIG. 1.3 shows a front view of the server rack (110) in accordance with one or more embodiments disclosed herein. The CDU (100) is connected to a facility supply line (141) and a facility return line (142). The inlet line (131) and the outlet line (132) are provided to the servers (111) via a manifold (145) of the servers (111). As discussed above, the server may include computing devices that generate heat during operation. If left unchecked, a buildup of heat within the server may cause temperatures of the components disposed within the server to exceed preferred ranges. The CDU (100) and coolant system is provided to remove heat from the server.

To do so, the CDU (100) is connected to the facility supply line (141) that provides a flow of facility coolant (e.g., water, non-conductive fluid, or any other liquid suitable for cooling components in a server) to a heat exchanger in the CDU (100) to the coolant in the CDU (100). The facility coolant exchanges heat with the coolant to cool it which is then provided to the servers via the CDU (100). The CDU (100) provides flow control of the coolant for the coolant system. The CDU (100) is shown to be mounted in the rack with the servers. In one or more embodiments, the CDU (100) is not mounted in the rack with the servers and may be attached to multiple server racks. In one embodiment, the CDU (100) is positioned in a section separate from the servers.

Continuing with the discussion of coolant flows, the cooled coolant exits the CDU (100) and flows into a CDU supply line to the inlet line (131). The inlet line (131) is positioned in the manifold (145). In one or more embodiments, the inlet line (131) is a singular piece of the manifold. The manifold (145) and the inlet line (131) are configured to receive a coolant flow from the CDU (100) and split that flow amongst the severs fluidly coupled to the manifold as shown in FIG. 3.2. Coolant flows through the manifold (145) and provides flow to the servers that are connected to the manifold (145). In FIG. 3.1, the manifold exists in two parts, a part containing the inlet line (131) shown on the right and a part containing the outlet line (132) shown on the left.

To do so, the manifold (145) is mechanically coupled to the server rack (110). In one or more embodiments, the mechanical coupling between the server rack (110) and the manifold (145) provides structural support for the manifold (145) while also positioning inlets and outlets of the servers to the manifold (145) in locations convenient for fluid coupling. The manifold (145) includes outlets configured to supply coolant flows to the servers and inlets configured to receive coolant flows from the servers. For example, the manifold (145) may include one outlet and one inlet for each server. The coolant then flows out of a manifold at a coolant outlet and into server inlet. From there, the fluid passes through the server and exchanges heat with one or more cold plates of one or more components within the server to remove heat from the server. For a more detailed discussion of the fluid flows between the manifolds and the chassis, see FIG. 1.4 below.

Next, the coolant flows out of the server through a server outlet, and returns to the manifold (145), entering the manifold (145) through a coolant inlet. The coolant then flows through the outlet line (132) of the manifold (145) and exits the manifold (145) through a manifold outlet. The coolant flows out of the manifold and enters a CDU return line to the CDU (100) through a unit inlet. The coolant may then be processed (i.e., cooled) by the CDU (100) by exchanging heat with facility coolant as described above. The facility coolant may flow out of the CDU (100) and flow into the facility return line (142) to be cooled after exchanging heat with the coolant.

FIG. 1.4 shows a diagram of a cooling system in accordance with one or more embodiments disclosed herein. For illustrative purposes, the cooling system shows the CDU (100) connection with only a single server (e.g., server A (111A)) of the plurality of servers (111); however, any number of chassis may be fluidly coupled to the manifold (145). The CDU (100) is connected to a manifold (145) via an inlet coolant flow (152) and an outlet coolant flow (153). The manifold (145) includes the inlet line (131) and the outlet line (132). Server A (111A) includes a computing component A (151A), a computing component B (151B), a computing component C (151C), and a computing component D (151D).

The computing component A (151A) is connected to a cold plate A (150A) which removes heat from the computing component A (151A). The cold plate A (150A) is connected to an inlet coolant flow (154) and an outlet coolant flow (155). The inlet coolant flow (154) is configured to provide cooled coolant to the cold plate A (151A). The inlet coolant flow (154) is connected to the inlet line (131) of the manifold (145). A digital solenoid valve A (130A) is located on the inlet coolant flow (154) to control the amount of coolant flowing to the cold plate A (150A). In one or more embodiments, the digital solenoid valve A (130A) may be adjusted between fully open and fully closed to adjust the mass flow rate of coolant to the cold plate A (150A). The outlet coolant flow (155) is configured to remove coolant from the cold plate A (151A) after the coolant is heated to remove heat from the computing component A (151A). The outlet coolant flow (155) is connected to the outlet line (132) of the manifold (145).

The computing component B (151B) is connected to a cold plate B (150B) which removes heat from the computing component B (151B). The cold plate B (150B) is connected to an inlet coolant flow (154) and an outlet coolant flow (155). The inlet coolant flow (154) is configured to provide cooled coolant to the cold plate B (150B). The inlet coolant flow (154) is connected to the inlet line (131) of the manifold (145). A digital solenoid valve B (130B) is located on the inlet coolant flow (154) to block and allow coolant flow to the cold plate B (150B). In one or more embodiments, the digital solenoid valve B (130B) may be adjusted between fully open and fully closed to adjust the mass flow rate of coolant to the cold plate B (150B). The outlet coolant flow (155) is configured to remove coolant from the cold plate B (150B) after the coolant is heated to remove heat from the computing component B (151B). The outlet coolant flow (155) is connected to the outlet line (132) of the manifold (145).

The computing component C (151C) is connected to a cold plate C (150C) which removes heat from the computing component C (151C). The cold plate C (150C) is connected to an inlet coolant flow (154) and an outlet coolant flow (155). The inlet coolant flow (154) is configured to provide cooled coolant to the cold plate C (150C). The inlet coolant flow (154) is connected to the inlet line (131) of the manifold (145). A digital solenoid valve C (130C) is located on the inlet coolant flow (154) to block and allow coolant flow to the cold plate C (150C). In one or more embodiments, the digital solenoid valve C (130C) may be adjusted between fully open and fully closed to adjust the mass flow rate of coolant to the cold plate C (150C). The outlet coolant flow (155) is configured to remove coolant from the cold plate C (150C) after the coolant is heated to remove heat from the computing component C (151C). The outlet coolant flow (155) is connected to the outlet line (132) of the manifold (145).

The computing component D (151D) is connected to a cold plate D (150D) which removes heat from the computing component D (151D). The cold plate D (150D) is connected to an inlet coolant flow (154) and an outlet coolant flow (155). The inlet coolant flow (154) is configured to provide cooled coolant to the cold plate D (150D). The inlet coolant flow (154) is connected to the inlet line (131) of the manifold (145). A digital solenoid valve D (130D) is located on the inlet coolant flow (154) to block and allow coolant flow to the cold plate D (150D). In one or more embodiments, the digital solenoid valve D (130D) may be adjusted between fully open and fully closed to adjust the mass flow rate of coolant to the cold plate D (150D). The outlet coolant flow (155) is configured to remove coolant from the cold plate D (150D) after the coolant is heated to remove heat from the computing component D (151D). The outlet coolant flow (155) is connected to the outlet line (132) of the manifold (145).

For conciseness the coolant path will be described for only computing component A (151A). A person of ordinary skill in the art would recognize the coolant path would be the same for the computing component B (151B), the computing component C (151C), and the computing component D (151D). Coolant flows out from the CDU (100), through an inlet coolant flow (152), and into the inlet line (131) of the manifold (145). The fluid then flows through the inlet line (131) and is distributed to the computing component A (151A) of server A (111A) fluidly coupled to the manifold (145).

To distribute the coolant to the computing component A (151A), the coolant flows out of the inlet line (131) through the digital solenoid valve A (130A) and into the inlet coolant flow (154). The fluid then flows into the cold plate A (150A) through an inlet. The coolant then exchanges heat with computing component A (151A) while in the cold plate A (150A) and exits the cold plate A (150A) through an outlet. Then, the coolant flows through the outlet coolant flow (155) to return to the outlet line (132) of the manifold (145). The coolant then flows through the outlet line (132) where it may join other flows returning from other components and servers. The coolant then flows out of the manifold (145) through an outlet coolant flow (153) and back into the CDU (100). As discussed above, the CDU (100) may then process the fluid and send it back through the inlet coolant flow (152), or the CDU (100) may send the fluid to a facility return line so that the fluid may be processed elsewhere.

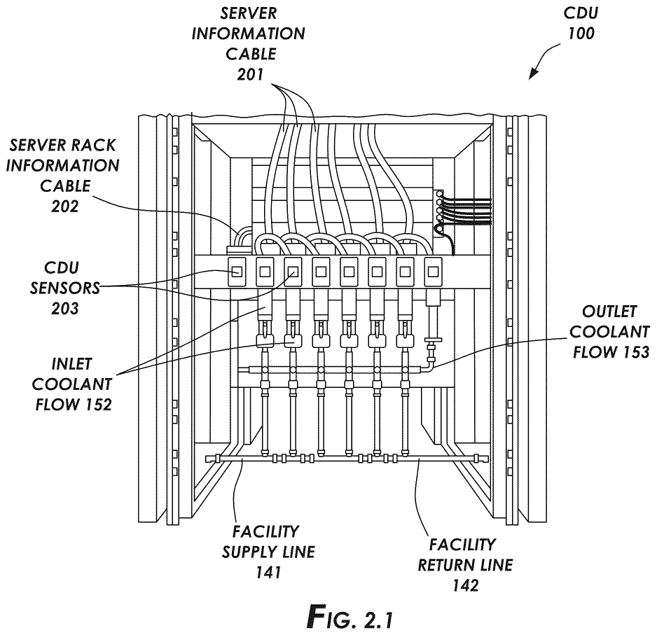

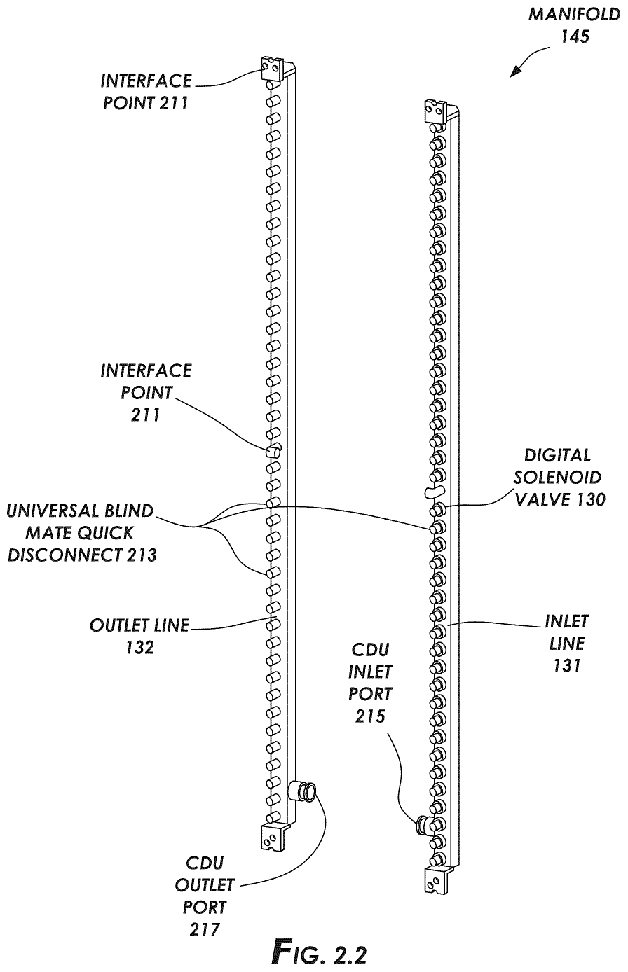

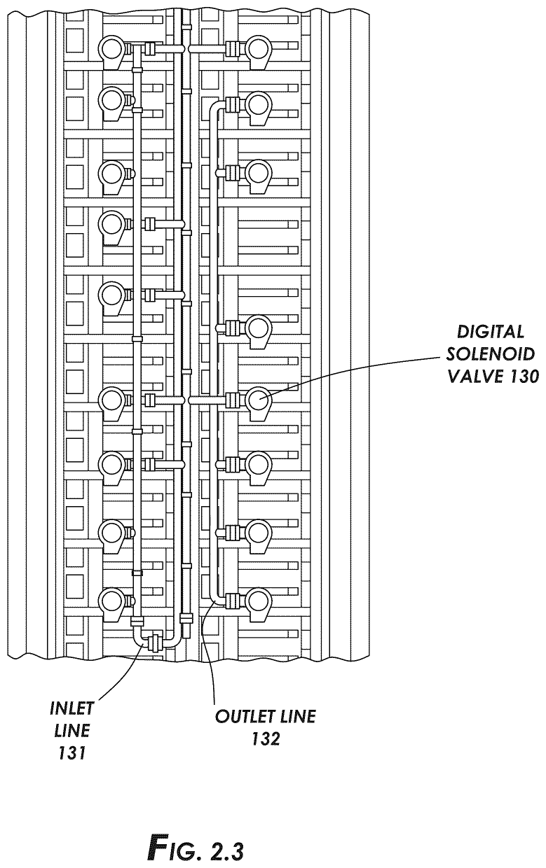

Turning to FIG. 2.1 shows a diagram of the CDU (100) in accordance with one or more embodiments disclosed herein. The CDU (100) includes a plurality of server information cables (201), a server rack information cable (202), a plurality of CDU sensors (203), the inlet coolant flow (152), and the outlet coolant flow (153). The CDU (100) is connected to the facility supply line (141) and the facility return line (142). Facility coolant in the facility supply line (141) and the facility return line (142) exchange heat with the coolant in the inlet coolant flow (152). The CDU (100) may be positioned in the bottom of the server rack (110) connected to a CDU inlet port (215), and a CDU outlet port (217) shown in FIG. 2.2. Plumbing lines connect to all the servers in the server rack (110) from the CDU (100) via the manifold (145) which is connected to the inlet coolant flow (152), and the outlet coolant flow (153). The digital solenoid valves (130) are controlled by the CDU (100). When a specific server needs to be shutoff, the digital solenoid valve (130) is completely closed, and the coolant is selectively shutoff to the specific server in the server rack (110) and the server is powered down. When a specific cold plate needs to be shut down and not the entire server, then the CDU selectively identifies the cold plate ID and closes the digital solenoid valve (130) for that specific cold plate shutting off the coolant supply to the specific cold plate and the component connected to the specific cold plate is powered down. Since the digital solenoid valve (130) for the entire server is not shut off, the coolant to the remaining cold plates is unaffected.

Each server's outlet plumbing lines return the hot coolant from the cold plates to the CDU (100) via the manifold which is connected to the outlet coolant flow (153) where the hot coolant is cooled by the CDU (100) by exchanging heat with facility coolant from the facility supply line (141). Once cooled, the coolant is sent back to the servers in the server rack (110) by the inlet coolant flow (152) via the manifold. The facility coolant is cooled outside the CDU (100) via a facility heat exchanger (not shown) and is transferred to the facility heat exchanged via the facility return line (142).

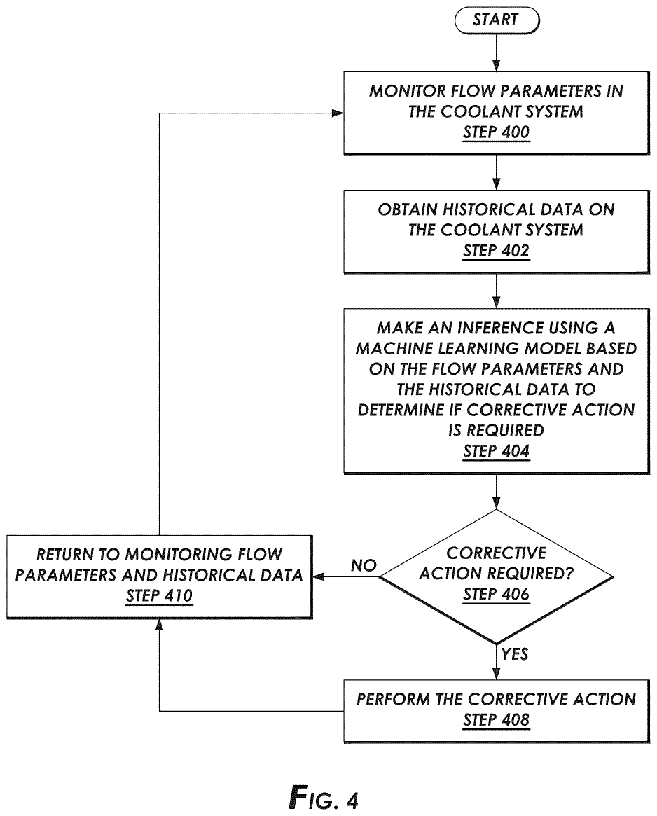

The plurality of server information cables (201) connects to each server to receive information on flow parameters discussed in FIG. 4. The server rack information cable (202) connects to the server rack itself and the DCIM (120) to allow the exchange of information between the CDU (100) and the DCIM (120). In one or more embodiments, the server rack information cable (202) connects to a graphical user interface (not shown) to provide users with alerts on the operations of the CDU (100). The plurality of CDU sensors (203) are connected to the servers via the plurality of server information cables and work to create and collect flow parameters in the CDU (100), the servers, the coolant lines, and the cold plates.

FIG. 2.2 shows a diagram of the manifold (145) for the server rack (110) in accordance with one or more embodiments disclosed herein. In one or more embodiments, the manifold (145) may include two separate manifolds as shown in FIG. 2.2. In one or more embodiments, the manifold (145) is a single manifold. The manifold (145) includes the inlet line (131), the outlet line (132), the plurality of digital solenoid valves (130), a plurality of interface ports (211), a plurality of universal blind mate quick disconnect (213), a CDU inlet port (215), and a CDU outlet port (217). In embodiments with two manifolds, the inlet line (131), and the CDU inlet port (215) may be on a single manifold and the outlet line (132), and the CDU outlet port (217) may be on a single manifold. The plurality of interface ports (211) is the connector of the manifold (145) and each server that connects to the manifold (145). The plurality of interface ports (211) allows for coolant flow between the inlet line (131), the outlet line (132), and the servers. The plurality of universal blind mate quick disconnect (213) connect the manifold (145) to the server rack (110). A person of ordinary skill in the art would recognize that other forms of connection including any dripless connector may be used to connect the manifold (145) to the server rack (110). The dripless connector allows for removal of the manifold (145) from the server rack (110) for maintenance on the inlet line (131) and the outlet line (132).

FIG. 2.3 shows a side view of a portion of the server rack in accordance with one or more embodiments disclosed herein. The side view shows the inlet line (131), the outlet line (132), and the plurality of digital solenoid valves (130). As shown in FIG. 2.3, the inlet line (131) and the outlet line (132) do not have to be straight up from the CDU (100) to maximize use of space. As shown in FIG. 2.3, in one or more embodiments, digital solenoid valves (130) may be used on the outlet line (132).

Turning to FIG. 3, FIG. 3 shows a flowchart for a method for responding to leaks in a computing system in accordance one or more embodiments disclosed herein. The method of FIG. 3 may be performed by, for example, the CDU (e.g., 100, FIG. 1.1) and the DCIM (e.g., 120, FIG. 1.1). Other components of the system of FIG. 1 may perform all, or a portion, of the method of FIG. 3 without departing from the disclosure.

While the various steps in the flowchart of FIGS. 3-7 are presented and described sequentially, one of ordinary skill in the relevant art will appreciate that some or all of the steps may be executed in different orders, may be combined, or omitted, and some or all steps may be executed in parallel.

In Step 300, the CDU monitors for a leak in the coolant system connecting a plurality of servers to the CDU. In one or more embodiments, the CDU is located in a server rack containing the plurality of servers. In one or more embodiments, the CDU is connected to a plurality of server racks which have the plurality of servers contained therein. The CDU may monitor for the leak using temperature readings from the plurality of servers, mass flow rates of coolant in different areas of the coolant system, or detecting moisture. The CDU controller of the CDU is connected to a plurality of sensors disposed within the plurality of servers to receive this information. In one or more embodiments, the CDU may monitor leaks at multiple cold plates embedded into the servers as well as at the servers themselves to allow for isolation of leaks to a single cold plate.

In Step 302, the CDU makes a first determination whether a leak is detected in the coolant system. If YES, the method proceeds to Step 304. If NO, the method reverts to Step 300. As discussed above the CDU may use different monitoring methods to discover a leak. If no leak is detected, the CDU continues to monitor as in Step 300. For example, when monitoring for a first leak, the CDU detects a drop in the flow rate of coolant to a first server. The CDU determines that the first leak at a first cold plate of a first computing component (e.g., graphics processing unit) of the first server.

In Step 304, the CDU shuts off a solenoid valve to contain the detected leak in the coolant system. The solenoid valve is positioned on a path of the coolant to the server with the detected leak. The CDU controller is connected to the solenoid valve and may shut off and open the solenoid valve. When the solenoid valve is shut off, no coolant can pass and reach the leak preventing more coolant from leaking in the server. Returning to the example in Step 302, the CDU shuts off a first solenoid valve which blocks the flow of coolant to the first cold plate.

In Step 306, the CDU transmits an identification of a server connected to the solenoid valve to the DCIM. The transmission indicates what server and components of the server were affected by a leak and shut down. With coolant being shut off computing components must be powered down to avoid a thermal runaway that can damage the server. The CDU controller using a server mapper (e.g., 102, FIG. 1.1) identifies the server affected by the coolant shut off and transmits this identification to be able to power down the affected computing components. When the coolant is shut off to an entire server, the CDU transmits a server rack (e.g., rack identification), a row, and a server ID to the DCIM. When the coolant is only shut off to particular cold plates in a server, the CDU transmits rack, a row, a server ID and a cold plate ID is sent to the DCIM. Returning to the example in Step 304, the CDU transmits a rack identification, row, and server ID for the first server and a cold plate ID for the first cold plate to the DCIM indicating that the coolant was shut off to the first cold plate.

In Step 308, the DCIM powers down an affected portion of the server. The DCIM is connected to the plurality of servers and can power up and power down the servers and components of the servers. In response to receiving the identification of the server, the DCIM powers down the affected portions of the server. In one or more embodiments, the DCIM powers down an entire server as all coolant flow to that server has been shut down. In one or more embodiments, the DCIM powers down one or more computing components that are affected by the shut down of coolant flow to the corresponding cold plates. Returning to the example in Step 306, the DCIM powers down the graphics processing unit connected to the first cold plate that is not receiving coolant. After Step 308, the method may end.

FIG. 4 shows a flowchart for a method for detecting anomalies in a coolant system of a computing system in accordance one or more embodiments disclosed herein. The method of FIG. 4 may be performed by, for example, the CDU (e.g., 100, FIG. 1.1) and the DCIM (e.g., 120, FIG. 1.1). Other components of the system of FIG. 1 may perform all, or a portion, of the method of FIG. 4 without departing from the disclosure.

In Step 400, the CDU monitors flow parameters in the coolant system. The coolant system connects the CDU to cold plates in a plurality of servers in the computing system. The flow parameters may include current temperature readings in the plurality of servers and CDU. The flow parameters may also include the flow rate and pressure data of coolant throughout the coolant system including in and out of the cold plates of the plurality of servers. In one or more embodiments, the power intake of each server of the plurality of servers is monitored along with the flow parameters. In one or more embodiments, a flow parameter is monitoring coolant quality (e.g., pH, conductivity, and particulate levels). The CDU controller (e.g., 101, FIG. 1.1) stores the flow parameters for use in anomaly detection. The flow parameters may be monitored using sensors in the coolant system connected to the CDU.

In Step 402, the CDU obtains historical data on the coolant system. The historical data includes historical temperatures of coolant flowing from the CDU, into the CDU, entering the plurality of cold plates and exiting the plurality of cold plates. The historical data further includes historical flow rates and historical pressure data of the coolant flowing from the CDU, into the CDU, entering the plurality of cold plates and exiting the plurality of cold plates. Prior leak occurrences in the computing system are also covered by historical data. In one or more embodiments, the historical data includes historical power intake of the plurality of servers. In one or more embodiments, historical data includes historical coolant quality (e.g., pH, conductivity, and particulate levels). The historical data may be stored in the historical data storage (e.g., 103, FIG. 1.1) for use in anomaly detection.

In Step 404, the CDU makes an inference using a machine learning model (e.g., 104, FIG. 1.1) based on the flow parameters and the historical data to determine if corrective action for the coolant system is required. The flow parameters and the historical data are inputs to the machine learning model. The machine learning model outputs corrective action. In one or more embodiments, the corrective action may be based on anomalies detected in the coolant system. The anomalies might be a potential leak or a leak that cannot be detected by the CDU using only sensor readings. A potential leak that can be fixed by preventative maintenance repairing the potential leak before the leak occurs. In one or more embodiments, the corrective action may be an action the CDU may perform (e.g., increase the flow rate, lower the coolant temperature, etc.).

In Step 406, the CDU makes a first determination whether the corrective action is required. If YES, the method proceeds to Step 408. If NO, the method proceeds to Step 410. For example, the machine learning model may output corrective action required based on an anomaly in the coolant system (e.g., a temperature spike and flow rate drop at a first cold plate in a first server when the first server power intake spikes during a high load time).

In Step 408, the CDU performs the corrective action. In one or more embodiments, the corrective action for the CDU may be handled by the CDU such as increasing the flow rate or lowering the coolant temperature. In one or more embodiments, the corrective action is preventative maintenance, and the CDU alerts a user to the need for preventative maintenance using a graphical user interface that provides a description of the user and a server ID of the affected server. Preventative maintenance may include (i) cleaning a cold plate, (ii) cleaning coolant line leading to a cold plate, (iii) cleaning a server, (iv) replacing a cold plate, (v) replacing a coolant line, and (vi) replacing a component of a server or the server itself. A potential leak can be fixed by preventative maintenance by repairing the potential leak before the leak occurs. Returning to the example from Step 406, the CDU based on the corrective action from the machine learning model, alerts a user to perform preventative maintenance on the coolant line at the first cold plate in the first server. The user discovers and removes a partial blockage of the coolant line preventing a leak from occurring if the line were left to break.

In Step 410, the CDU returns to monitoring the flow parameters and the historical data. The CDU returns to monitoring the flow parameters and the historical data after the corrective action is performed or after the inference of no corrective action is received from the machine learning model. After Step 410, the method reverts to Step 400.

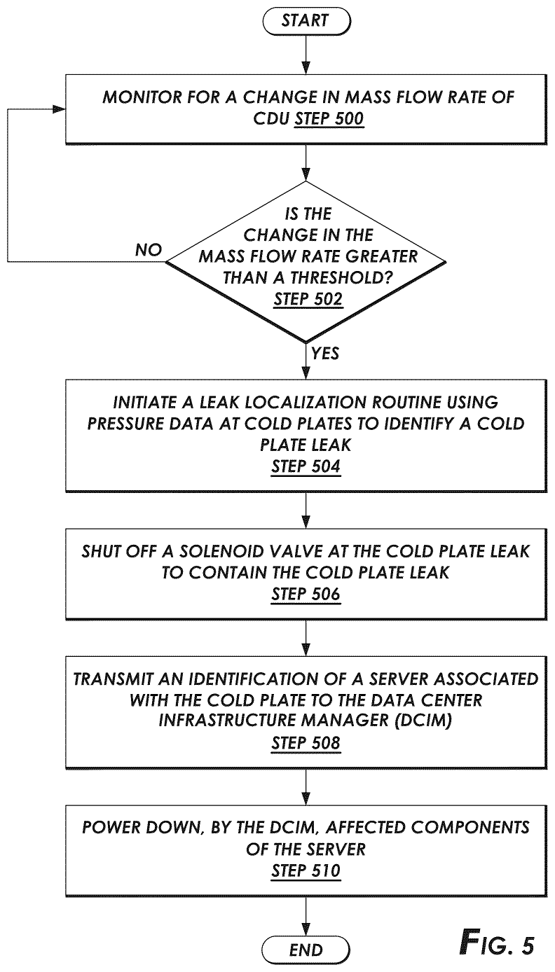

FIG. 5 shows a flowchart for a method for responding to leaks in a computing system in accordance one or more embodiments disclosed herein. The method of FIG. 5 may be performed by, for example, the CDU (e.g., 100, FIG. 1.1) and the DCIM (e.g., 120, FIG. 1.1). Other components of the system of FIG. 5 may perform all, or a portion, of the method of FIG. 5 without departing from the disclosure.

In Step 500, the CDU monitors for a change in a mass flow rate at the CDU. The server one of a plurality of servers connected to the CDU via a coolant system to remove heat from the servers. The CDU checks the mass flow rate using a CDU controller (e.g., 101, FIG. 1.1) connected to sensors in CDU and the coolant line connected to the CDU.

In Step 502, the CDU makes a first determination whether there is a change in the mass flow rate greater than a threshold. The threshold is set prior to the method and indicates a drop in the mass flow rate that is probably caused by a leak in the coolant system. If YES, the method proceeds to Step 504. If NO, the method reverts to Step 500.

In Step 504, the CDU initiates a leak localization routine using pressure data at cold plates to identify a cold plate leak. The cold plates are positioned in servers of the plurality of servers to facilitate the removal of heat from the servers. The CDU controller uses sensors in the cold plates to determine a drop of pressure of coolant in the cold plates. The CDU determines a first cold plate has a pressure drop and is the leak is in the coolant line leading to the first cold plate.

In Step 506, the CDU shuts off a solenoid valve at the cold plate leak to contain the cold plate leak. The solenoid valve is positioned on a path between the cold plate and the CDU with the detected leak. The CDU controller is connected to the solenoid valve and may shut off and open the solenoid valve. When the solenoid valve is shut off, no coolant can pass and reach the leak preventing more coolant from leaking in the server.

In Step 508, the CDU transmits an identification of a server associated with the cold plate to the DCIM. The transmission indicates what server and components of the server were affected by a leak and shut down. With coolant being shut off computing components must be powered down to avoid a thermal runaway that can damage the server. The CDU controller using a server mapper (e.g., 102, FIG. 1.1) identifies the server affected by the coolant shut off and transmits this identification to be able to power down the affected computing components. The CDU transmits rack, a row, a server ID and a cold plate ID to the DCIM.

In Step 510, the DCIM powers down affected components of the server. The DCIM is connected to the plurality of servers and can power up and power down the servers and components of the servers. In response to receiving the identification of the server, the DCIM powers down the affected portions of the server. In one or more embodiments, the DCIM powers down one or more computing components that are affected by the shutdown of coolant flow to the first cold plate.

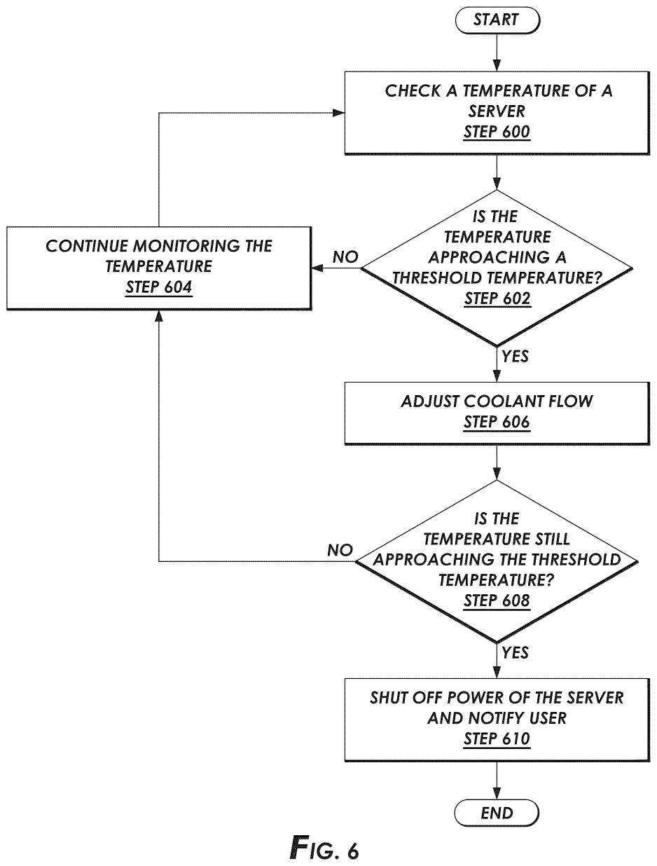

FIG. 6 shows a flowchart for a method for responding to leaks in a computing system in accordance one or more embodiments disclosed herein. The method of FIG. 6 may be performed by, for example, the CDU (e.g., 100, FIG. 1.1) and the DCIM (e.g., 120, FIG. 1.1). Other components of the system of FIG. 6 may perform all, or a portion, of the method of FIG. 6 without departing from the disclosure.

In Step 600, the CDU checks a temperature of a server including the average temperature of the server, the temperature of components of the server such as cold plates, the case of the server, and the temperature of the computing components of the server including the junction temperature of the semiconductor in the computing components. The server one of a plurality of servers connected to the CDU via a coolant system to remove heat from the servers. The CDU checks the temperature using a CDU controller (e.g., 101, FIG. 1.1) connected to sensors in the server. For example, the CDU checks the temperature of a first server and calculates a first temperature of 64 degrees Celsius (C).

In Step 602, the CDU makes a first determination whether the temperature is approaching a threshold temperature. The threshold temperature is set prior to the method and includes a factor of safety from a temperature that will cause damage or affect computational speed of the server. In one or more embodiments, approaching the threshold temperature provides an additional layer of safety. In one or more embodiments, approaching considers a rate of temperature change towards the threshold temperature based on multiple temperature checks. If YES, the method proceeds to Step 606. If NO, the method proceeds to Step 604. Returning to the example from Step 600, the threshold temperature is 65 degrees C, and the CDU determines that the first server is approaching the threshold temperature.

In Step 604, the CDU continues to monitor the temperature of the server. Step 604 is reached if the CDU does not detect a temperature approaching the threshold temperature or if mitigation efforts in Step 606 are successful at lowing the temperature a safe amount under the threshold temperature. After Step 604, the method reverts to Step 600.

In Step 606, the CDU adjusts a coolant flow. The CDU adjusts the coolant flow to attempt to reduce or stabilize the temperature of the first server. The CDU may adjust the coolant flow by reducing a coolant temperature of the coolant flow. The CDU may adjust the coolant flow by increasing a mass flow rate of the coolant. The CDU may adjust the coolant flow by both increasing the mass flow rate and reducing the coolant temperature of the coolant. Returning to the example from Step 602, the CDU reduces the coolant temperature and increases the mass flow rate of the coolant to try to reduce the first temperature.

In Step 608, the CDU makes a second determination whether the temperature is still approaching the threshold temperature. The CDU checks the temperature again and determines if the temperature is still approaching the threshold temperature. If the temperature has stabilized below the threshold temperature or is decreasing under the threshold temperature the temperature is not still approaching the threshold temperature. If not, the temperature is still approaching the threshold temperature. If YES, the method proceeds to Step 610. If NO, the method reverts to Step 604. Returning to the example from Step 606, the CDU determines the temperature has increased to 64.5 degrees C and therefore is still approaching the threshold temperature.

In Step 610, the DCIM shuts off power to the server and notifies a user. To protect the server from a dangerous thermal runaway or prolonged exposure to dangerous temperatures, the server must be powered off to cool down and fix the issue causing the dangerous temperatures. The CDU sends a server ID and Rack ID of the server to the DCIM with instructions to shut down the server. The DCIM shuts down the server.

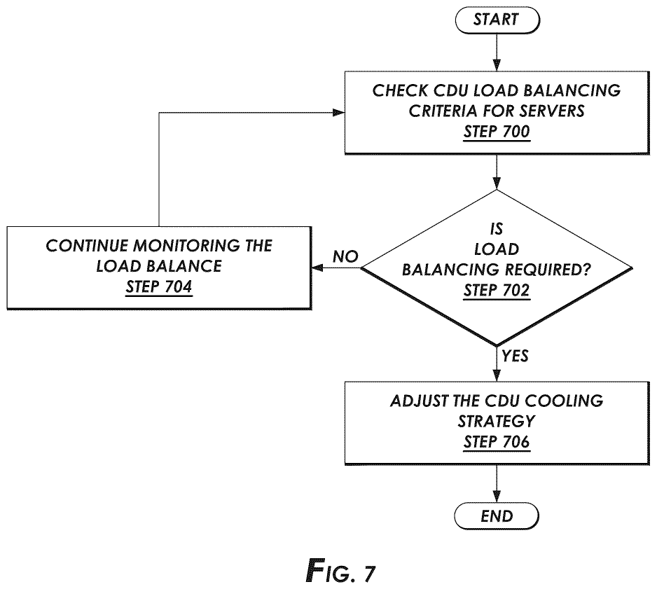

After Step 610, the method may end. In one or more embodiments, the method of FIG. 6 may be combined with the method of FIG. 7 to allow for flow rate and temperature monitoring at the same time. In one or more embodiments, the method can be focused on single computing components in the server to avoid powering down the entire server.

FIG. 7 shows a flowchart for a method for load balancing a computing system in accordance one or more embodiments disclosed herein. The method of FIG. 7 may be performed by, for example, the CDU (e.g., 100, FIG. 1.1) and the DCIM (e.g., 120, FIG. 1.1). Other components of the system of FIG. 7 may perform all, or a portion, of the method of FIG. 6 without departing from the disclosure.

In Step 700, the CDU checks a CDU load balancing criteria for servers of the computing system. A CDU controller (e.g., 101, FIG. 1.1) of the CDU checks the CDU load balancing criteria using an appropriate algorithm based on a predetermined mapping of the algorithms in the CDU. The appropriate algorithms may include a location aware load balancing scheme, a thermal aware load balancing scheme, a workload aware load balancing scheme, a power aware load balancing scheme, and a frequency aware load balancing scheme. In one or more embodiments, prior to checking the CDU load balancing criteria, the CDU receives a request from a one or more servers of the computing system to perform a load balancing. In one or more embodiments, the CDU load balancing criteria is used to preemptively determine the server will exceed a threshold temperature during operation.

The location aware load balancing scheme balances the workload of servers based on location in a plurality of server racks of the computing system. The algorithm choice depends on the desired level of control over server selection in different locations. Suitable algorithms in the location aware load balancing scheme include round robin, weighted round robin, and random. The thermal aware load balancing scheme adapts to a temperature of the server in real time. These algorithms are best suited from adapting to real-time server temperatures. Suitable algorithms in the thermal aware load balancing scheme include least connections, weighted least connections.

The workload aware load balancing scheme assigns a weight to the server compared to other servers based on workload type (e.g., the server's ability to handle different workload types like high-performance computing). Suitable algorithms in workload aware load balancing scheme include weighted least connections and weighted round robin. The power aware load balancing scheme assigns a weight to the server compared to other servers based on power consumption and capacity. The weights can also include connection counts. Suitable algorithms in the power aware load balancing scheme include weighted least connection. The frequency aware load balancing scheme causes the first server to scale power intake based on workload. This involves dynamic voltage and frequency scaling (DVFS) techniques within individual servers rather than a separate load balancing algorithm. The computing components in the individual servers (e.g., central processing unit or graphics processing unit) perform the DVFS in the individual servers. Therefore, the frequency aware load balancing scheme is used mostly when the server initiates the load balancing check.

In Step 702, the CDU makes a first determination whether load balancing is required. The CDU controller makes the first determination using factors such an information technology load, a workload change, and power dissipation in the server. The CDU compares the factors to the other servers and if the factors are higher in the server compared to the other servers a load balance is needed. If YES, the method proceeds to Step 706. If NO, the method proceeds to Step 704.

In Step 704, the CDU continues to monitor the load balance to determine if load balancing is required. After Step 704, the method reverts to Step 700.

In Step 706, the CDU adjusts the CDU cooling strategy. Prior to adjusting the CDU cooling strategy, the CDU makes a second determination to identify the location of the server to determine where to adjust the CDU cooling strategy. The CDU may identify the location of the server using the identification methods discussed above such as the server mapper (e.g., 102, FIG. 1.1). Once the location of the server is identified, the CDU adjusts the CDU cooling strategy based on the suitable algorithm chosen by the CDU by modifying a coolant flow to the server to rebalance the CDU load balance criteria. In one or more embodiments, the coolant flow is modified to reduce a coolant temperature of the coolant flow. In one or more embodiments, the coolant flow is modified to increase a mass flow rate of coolant.

After the CDU adjusts the load balance, which, as described above, can include adjusting the cooling strategy, the chosen suitable algorithm outputs a data table. An example output data table is shown below.

| | | | Load | Chosen | T (C) prior | T (C) |
|---|---|---|---|---|---|---|
| | Grid | | Balancing | Suitable | to load | after load |
| Rack ID | Location | Server ID | Scheme | Algorithm | balancing | balancing |
| {‘rack-326 | 11 6 | {‘server- | {‘Location | {‘Round | 78 | 66 |
| (CDU- | | 9’} | Aware’} | Robin’} | | |
| 326)’} | | | | | | |
| {‘rack-549 | 18 5 | {‘server- | {‘Thermal | {‘Least | 72 | 58 |
| (CDU- | | 3’} | Aware’} | Connections’} | | |
| 549)’} | | | | | | |
| {‘rack-936 | 30 8 | {‘server- | {‘Workload | {‘Weighted | 77 | 66 |
| (CDU- | | 4’} | Aware’} | Round Robin’} | | |
| 936)’} | | | | | | |
| {‘rack-925 | 29 29 | {‘server- | {‘Frequency | {‘Dynamic | 74 | 62 |
| (CDU- | | 4’} | Aware’} | Voltage and | | |
| 925)’} | | | | Frequency | | |
| | | | | Scaling | | |
| | | | | (DVFS)’} | | |

The Rack ID, Grid Location, and Server ID are collected as described above when finding the location of the server. The load balancing scheme and chosen suitable algorithm are selected by the CDU in Step 700. T (C) prior to load balancing is the temperature in the server before the server is load balanced. T (C) after load balancing is the temperature after the server has been load balanced. The temperature may be an average temperature of the server itself of a portion of the server including the temperature of components of the server such as cold plates, the case of the server, and the temperature of the computing components of the server including the junction temperature of the semiconductor in the computing components. As is shown in the example data table, load balancing can reduce the temperature in a server 10 to 14 degrees C.

After Step 706, the method ends.

As discussed above, embodiments of the disclosure may be implemented using computing devices. FIG. 8 shows a diagram of a computing device in accordance with one or more embodiments disclosed herein. The computing device may include one or more computer processor(s) (802), non-persistent storage (804) (e.g., volatile memory, such as RAM, cache memory), persistent storage (806) (e.g., a hard disk, an optical drive such as a compact disk (CD) drive or digital versatile disk (DVD) drive, a flash memory, etc.), a communication interface (812) (e.g., Bluetooth interface, infrared interface, network interface, optical interface, etc.), input devices (810), output devices (808), and numerous other elements (not shown) and functionalities. Each of these components is described below.

In one embodiment of the disclosure, the processor(s) (802) may be an integrated circuit for processing instructions. For example, the computer processor(s) may be one or more cores or micro-cores of a processor. The computing device may also include one or more input devices (810), such as a touchscreen, keyboard, mouse, microphone, touchpad, electronic pen, or any other type of input device. Further, the communication interface (812) may include an integrated circuit for connecting the computing device to a network (not shown) (e.g., a local area network (LAN), a wide area network (WAN) such as the Internet, mobile network, or any other type of network) and/or to another device, such as another computing device.

In one embodiment of the disclosure, the computing device may include one or more output devices (808), such as a screen (e.g., a liquid crystal display (LCD), a plasma display, touchscreen, cathode ray tube (CRT) monitor, projector, or other display device), a printer, external storage, or any other output device. One or more of the output devices may be the same or different from the input device(s). The input and output device(s) may be locally or remotely connected to the computer processor(s) (802), non-persistent storage (804), and persistent storage (806). Many different types of computing devices exist, and the aforementioned input and output device(s) may take other forms.

Software instructions in the form of computer readable program code to perform embodiments described herein may be stored, in whole or in part, temporarily or permanently, on a non-transitory computer readable medium such as a CD, DVD, storage device, a diskette, a tape, flash memory, physical memory, or any other physical computer readable storage medium. Specifically, the software instructions may correspond to computer readable program code that, when executed by a processor(s), is configured to enable the computer processor to perform one or more embodiments described herein.

The problems discussed above should be understood as being examples of problems solved by embodiments of the disclosure disclosed herein and the disclosure should not be limited only to solving the same/similar problems. The disclosure is broadly applicable to address a range of problems beyond those discussed herein.

Specific embodiments are described with reference to the accompanying figures. In the above description, numerous details are set forth as examples. It will be understood by those skilled in the art, that one or more embodiments of the present disclosure may be practiced without these specific details, and that numerous variations or modifications may be possible without departing from the scope. Certain details known to those of ordinary skill in the art are omitted to avoid obscuring the description.

In the prior description of the figures, any component described with regard to a figure, in various embodiments of the disclosure, may be equivalent to one or more like-named components described with regard to any other figure. For brevity, descriptions of these components are not repeated with regard to each figure. Thus, each and every embodiment of the components of each figure is incorporated by reference and assumed to be optionally present within every other figure having one or more like-named components. Additionally, in accordance with various embodiments of the disclosure, any description of the components of a figure is to be interpreted as an optional embodiment, which may be implemented in addition to, in conjunction with, or in place of the embodiments described with regard to a corresponding like-named component in any other figure.

Throughout this application, elements of figures may be labeled as A to N. As used herein, the aforementioned labeling means that the element may include any number of items and does not require that the element include the same number of elements as any other item labeled as A to N unless otherwise specified. For example, a data structure may include a first element labeled as A and a second element labeled as N. This labeling convention means that the data structure may include any number of the elements. A second data structure, also labeled as A to N, may also include any number of elements. The number of elements of the first data structure and the number of elements of the second data structure may be the same or different.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as by the use of the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

As used herein, the phrase operatively connected, or operative connection, means that there exists between elements/components/devices a direct or indirect connection that allows the elements to interact with one another in some way. For example, the phrase ‘operatively connected’ may refer to any direct (e.g., wired directly between two devices or components) or indirect (e.g., wired and/or wireless connections between any number of devices or components connecting the operatively connected devices) connection. Thus, any path through which information may travel may be considered an operative connection.

Software instructions in the form of computer readable program code to perform embodiments described herein may be stored, in whole or in part, temporarily or permanently, on a non-transitory computer readable medium such as a CD, DVD, storage device, a diskette, a tape, flash memory, physical memory, or any other physical computer readable storage medium. Specifically, the software instructions may correspond to computer readable program code that, when executed by a processor(s), is configured to perform one or more embodiments described herein.

While the disclosure has been described above with respect to a limited number of embodiments, those skilled in the art, having the benefit of this disclosure, will appreciate that other embodiments can be devised which do not depart from the scope as disclosed herein. Accordingly, the scope of the disclosure should be limited only by the attached claims.

What is claimed is:

1. A method for load balancing a computing system, comprising:
checking a first load balancing criteria for a first server of the computing system using a controller of a coolant distribution unit (CDU), wherein the controller chooses an appropriate algorithm based on a predetermined mapping in the CDU;
making a first determination that the first load balancing criteria needs to be rebalanced wherein the controller uses an information technology load, a workload change, and a higher power dissipation in the first server to make the first determination;
making a second determination, based on the first determination, to identify a location of the first server; and
adjusting a CDU cooling strategy, based on the second determination, by modifying a first coolant flow to the first server to rebalance the first load balancing criteria.

2. The method of claim 1, further comprising:
checking a second load balancing criteria of a second server of the computing system;
making a third determination that the second load balancing criteria does not need to be rebalanced; and
continue monitoring, based on the third determination, the second load balancing criteria.

3. The method of claim 1, wherein the first load balancing criteria preemptively determines the first server will exceed a threshold temperature during operation.

4. The method of claim 1, wherein adjusting the CDU cooling strategy comprises reducing a coolant temperature of the first coolant flow.

5. The method of claim 1, wherein adjusting the CDU cooling strategy comprises increasing a mass flow rate of coolant.

6. The method of claim 1, wherein the appropriate algorithm is a location aware load balancing scheme that balances the workload of servers based on location in a plurality of server racks of the computing system.

7. The method of claim 1, wherein the appropriate algorithm is a thermal aware load balancing scheme that adapts to a temperature of the first server in real time.

8. The method of claim 1, wherein the appropriate algorithm is a workload aware load balancing scheme that assigns a weight to the first server compared to other servers based on workload type.

9. The method of claim 1, wherein the appropriate algorithm is a power aware load balancing scheme that assigns a weight to the first server compared to other servers based on power consumption and capacity.

10. A method for load balancing a computing system, comprising:
receiving, at a coolant distribution unit, a first request from a first server of the computing system to perform a load balancing;
checking a first load balancing criteria for the first server using a controller of the CDU, wherein the controller chooses an appropriate algorithm based on a predetermined mapping in the CDU;
making a first determination that the first load balancing criteria needs to be rebalanced wherein the controller uses an information technology load, a workload change, and a higher power dissipation in the first server to make the first determination;
making a second determination, based on the first determination, to identify a location of the first server; and
adjusting a CDU cooling strategy, based on the second determination, by modifying a first coolant flow to the first server to perform the load balancing.

11. The method of claim 10, further comprising:
receiving, at the CDU, a second request from a second server of the computing system to perform a second load balancing;
checking a second load balancing criteria of the second server;
making a third determination that the second load balancing criteria does not need to be rebalanced; and
continue monitoring, based on the third determination, the second load balancing criteria.

12. The method of claim 10, wherein adjusting the CDU cooling strategy comprises reducing a coolant temperature of the first coolant flow.

13. The method of claim 10, wherein adjusting the CDU cooling strategy comprises increasing a mass flow rate of coolant.

14. The method of claim 10, wherein the appropriate algorithm is a frequency aware load balancing scheme that causes the first server to scale power intake based on workload.

15. A non-transitory computer readable medium (CRM) comprising computer readable program code, which when executed by a computer processor enables the computer processor to perform a method for load balancing a computing system, the method comprising:
checking a first load balancing criteria for a first server using a controller of a coolant distribution unit (CDU), wherein the controller chooses an appropriate algorithm based on a predetermined mapping in the CDU;
making a first determination that the first load balancing criteria needs to be rebalanced wherein the controller uses an information technology load, a workload change, and a higher power dissipation in the first server to make the first determination;
making a second determination, based on the first determination, to identify a location of the first server; and
adjusting a CDU cooling strategy, based on the second determination, by modifying a first coolant flow to the first server to rebalance the first load balancing criteria.

16. The non-transitory CRM of claim 15, further comprising:
checking a second load balancing criteria of a second server of the computing system;
making a third determination that the second load balancing criteria does not need to be rebalanced; and
continue monitoring, based on the third determination, the second load balancing criteria.

17. The non-transitory CRM of claim 15, wherein the first load balancing criteria preemptively determines the first server will exceed a threshold temperature during operation.

18. The non-transitory CRM of claim 15, wherein adjusting the CDU cooling strategy comprises reducing a coolant temperature of the first coolant flow.

19. The non-transitory CRM of claim 15, wherein adjusting the CDU cooling strategy comprises increasing a mass flow rate of coolant.

20. The non-transitory CRM of claim 15, wherein the appropriate algorithm is a location aware load balancing scheme that balances the workload of servers based on location in a plurality of server racks of the computing system.
